(19) United States
(12) Patent Application Publication
(10) Pub. No.: US 2008/0142941 A1
(43) Pub. Date: Jun. 19, 2008

(54) 3D ELECTRONIC PACKAGING STRUCTURE WITH ENHANCED GROUNDING PERFORMANCE AND EMBEDDED ANTENNA

(75) Inventors: Ming-Chih Yew, Hsinchu City (TW); Chien-Chia Chiu, Thongli City (TW); Kou-Ning Chiang, Hsinchu City (TW); Wen-Kun Yang, Hsin-Chu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/612,563

(22) Filed: Dec. 19, 2006

(51) Int. Cl. H01L 23/02

(52) U.S. Cl. 257/686; 257/E23.085

(57) ABSTRACT

The present invention proposes a 3D electronic packaging structure with enhanced grounding performance and embedded antenna, and the packaging unit can achieve multi-chip stacking through the signal contacts on the top and bottom surfaces of the unit. A single or multiple grounding layers are on the back of the substrate in the packaging unit to facilitate the grounding for the semiconductor element; further, the packaging unit is applicable to a wafer level packaging process, so the manufacturing cost of each individual packaging unit is reduced. The above grounding layers are also the signal transmission paths of the electronic elements in the packaging structure of the invention, and a single or multiple via holes around the electronic element layers allow electrical signal connection between the top and bottom surfaces of the packaging structure, and thus enable more functionality in the packaging unit. Moreover, the grounding layers may have circular signal channels to construct a 3D stacked packaging structure with embedded antenna.

### FIELD OF THE INVENTION

The present invention relates to electronic packaging structures, and more particularly to a 3D packaging unit with enhanced grounding performance and embedded antenna, wherein a single or multiple grounding layers are on the back of the substrate in the packaging unit, which can achieve multi-chip stacking through the signal contacts on the both sides of the packaging unit.

### BACKGROUND OF THE INVENTION

Modern electronic products tend to be miniaturized, high-performance, high-accuracy, high-reliability, and high-reactivity; consequently, the distribution density of the circuit elements is overly high and the volume of the circuits decreases substantially. However, as the circuits of the electronic products become more delicate, more elements will be formed in the tiny space and susceptible to signal interferences from each other. As a result, the signal stability of the electronic products will be affected. The most common issues are Electromagnetic Interference (EMI) and noise. EMI is mainly divided into radiated and conducted EMI. Radiated EMI transmit directly through open space without any transmission medium, and thus can only be eliminated by shielding or grounding. The present invention discloses a 3D packaging unit with enhanced grounding performance, wherein a single or multiple grounding layers are on the back of the substrate to enhance electrical performance of the stacked packaging unit and to reduce EMI to the high-density electronic elements.

A stacked integrated circuit (IC) chip packaging of a prior art is disclosed in U.S. Pat. No. 6,387,728, referring to FIG. 1. A first IC chip 103 is placed on the top of a substrate 102 of a package 100, and wire bonding operation is performed on the first IC chip 103 to form multiple bonding wires 104 and electrically connect the first IC chip 103 and the substrate 102. Then, an adhesive layer 105 is coated on the top of the first IC chip 103 to adhere a second IC chip 106 to the top thereof. Similarly, multiple bonding wires 107 are formed by employing the wire bonding operation to connect the second IC chip 106 and the substrate 102, after the procedure, a molding material 108 is deployed on the substrate 102 to wrap up all components, thereby completing the packaging process of a stacked IC chip. Two or more chips are stacked together and share a substrate in the stacked IC packaging to save space effectively while increasing the number of chips. However, signal delay may occur frequently due to signal transmission inside chips can only be carried out after the bonding wires connect the substrate. In addition, since the signal transmission paths are too long in this packaging structure, noise may occur frequently if such structure applied to high frequency electronic elements, and thereby affect the signal reliability of the electronic elements.

A high density IC chip packaging structure is disclosed in U.S. Pat. No. 6,236,115, referring to FIG. 2. The packaging structure is formed by employing chip stacking, but to reduce the possible signal delay of signal transmission between chips caused by employing the bonding wires as discussed above, a first IC chip 201, a second IC chip 202 and a third IC chip 203 do not form electrical channels by the wire bonding operation. The patent mainly utilizes multiple via holes 206 being formed in the chips, and disposes metalized traces 204 on the hole walls and with conductive fixation structures 205, therefore the signal transmission paths between the chips are reduced effectively and the possibility of signal with noise decreases. Although the transmission paths between the chips can be reduced in the above packaging structure, the possibility of the signal interferences between different types of chips increases due to the increased distribution density of IC chips, and thus the signal stability of electronic products will be affected.

Accordingly, as system-on-chip (SOC) package is becoming a trend to manufacture multiple chips, such as microelectronics, high frequency communication or actuating sensors, and to reduce the technology cost of stacked packaging and to achieve packaging volume miniaturization, it is a pressing issue to develop a high-density, highly reliable structure and electrical properties, and to design and assemble a packaging structure with multi-microelectronic elements which can make flexible adjustment depending on required application functions.

### SUMMARY OF THE INVENTION

In the light of the drawbacks in the prior art as discussed above, and system-on-chip (SOC) package is becoming a trend to manufacture multiple chips, such as microelectronics, high frequency communication or actuating sensors, the objects of the present invention will be shown as follows:

The present invention proposes an electronic packaging structure, and the object is to provide a wafer-level packaging unit with multiple microelectronic elements, wherein the conductive trace patterns on the top and bottom surfaces can perform flexibly a single or multiple miniaturized stacked packaging structure depending on the requirements of application circumstances and functions to reduce the signal transmission paths and time, and thereby enhance the working frequency and efficiency of the stacked packaging module.

Another object of the invention is to provide an electronic packaging structure, wherein all packaging units are batch manufactured on wafers or substrates, and thus reduce the manufacturing cost of each individual packaging unit.

Still another object of the invention is to provide an electronic packaging structure, wherein a single or multiple grounding layers are on the back of the substrate to enhance the electrical performance, and thus Electromagnetic Interference (EMI) to high density electronic elements is reduced.

To accomplish the discussed purposes above, the proposed electronic packaging structure of the invention comprises a single or multiple substrates for forming electronic elements. A single or multiple electronic elements are formed on the first surfaces of the substrates, and the areas occupied by the electronic elements are smaller than or equal to those of the substrates. A single or multiple contact pads are disposed on the surfaces of the above electronic elements. A single or multiple buffer areas are distributed around the above electronic elements. A single or multiple grounding layers are formed on the second surfaces of the above substrates, wherein the above buffer areas include a single or multiple via holes formed thereon, and a conductive material is filled inside the via holes and hole walls to establish signal connection between the upper surfaces of the above buffer areas and the above grounding layers. A single or multiple signal channels are formed on at least one side of the above electronic packaging structure. A single or multiple signal contacts are formed at the ends of the above signal channels, and distributed over at least one side of the above electronic packaging structure.

The aforementioned objects, features, and advantages will become apparent from the following detailed description of a preferred embodiment taken together with the accompanying drawings.

### BRIEF DESCRIPTION OF THE DRAWINGS

A preferred embodiment of the invention will be illustrated further in the following description and accompanying drawings, and wherein:

FIG. 1 is a schematic diagram of a stacked IC chips packaging structure of a prior art.

FIG. 2 is a schematic diagram of a high density IC chips packaging structure of a prior art formed by employing wafer drilling.

FIG. 3A is a first embodiment of the present invention and a cross-sectional diagram (taken from the A-A′ line in FIG. 3B) of the packaging units of the invention.

FIG. 3B is a possible bottom view of the first embodiment of the invention, corresponding to FIG. 3A.

FIG. 4A is an enlarged view of a possible distribution on the substrate according to the first embodiment of the invention.

FIG. 4B is a possible cross-sectional view on the substrate according to the first embodiment of the present invention, corresponding to the enlarged area in FIG. 4A.

FIG. 5A is a schematic diagram of wafer stacking.

FIG. 5B is a side view of a separating or dicing process after the wafer stacking, corresponding to FIG. 5A.

FIG. 6 is a second embodiment of the present invention and a cross-sectional schematic diagram of a first-type stacked packaging configured by the packaging units of the present invention.

FIG. 7 is a third embodiment of the present invention and a cross-sectional schematic diagram of a second-type stacked packaging configured by the packaging units of the present invention.

FIG. 8 is a fourth embodiment of the present invention, and a cross-sectional schematic diagram of a third-type stacked packaging configured by the packaging units of the invention.

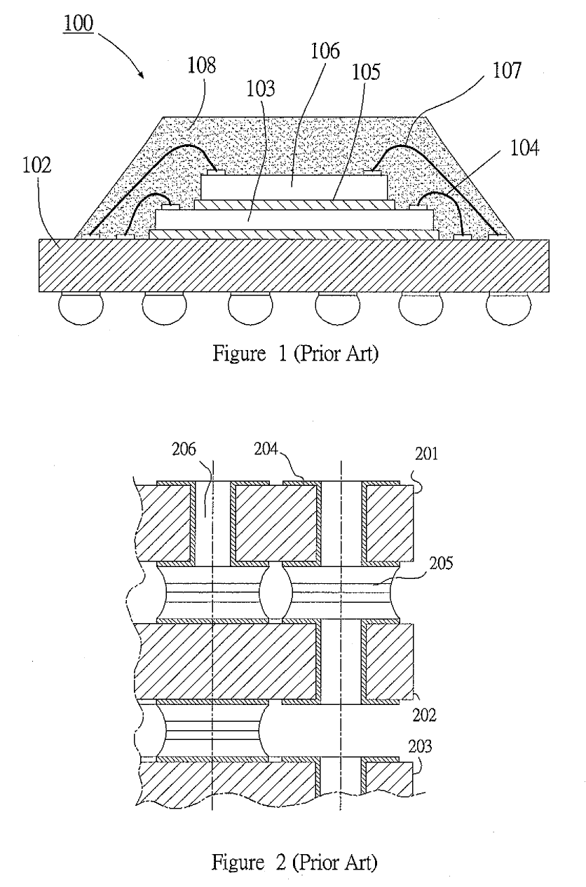

### DETAILED DESCRIPTION OF A PREFERRED EMBODIMENT

An electronic packaging structure is disclosed in the present invention. More specifically, the invention proposes a 3D packaging unit with enhanced grounding performance, which can achieve multi-chip stacking through the signal contacts on the both sides of the unit. The embodiments of the invention are described in detailed below, and the preferred embodiment is for illustration only and not for the purpose of limiting the invention.

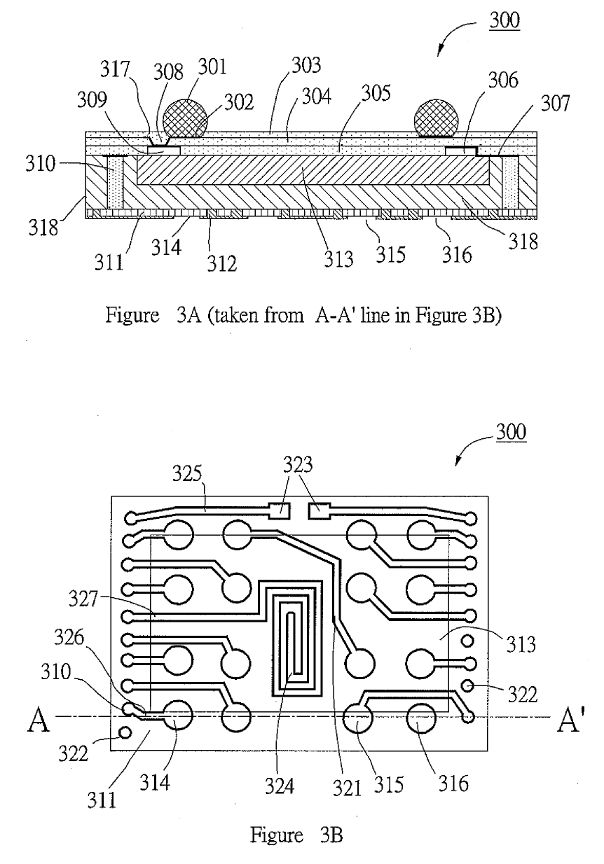

FIG. 3A is a cross-sectional diagram of a first packaging unit 300 of the present invention and it is taken from the A-A′ line in FIG. 3B. The material of substrate 318 in the preferred embodiment can be Si, Ge, Sn, C or the combinations of the above elements with other types of semiconductor elements. A first electronic element layer 313 is formed on the substrate 318 by employing well known semiconductor process, and the electronic element can be an active device, a passive device, a sensing device, a testing device, a micro-electro-mechanical (MEM) chip or the combinations thereof. On the substrate 318, the portion where the first electronic element layer 313 does not occupy is a buffer area (not shown specifically in FIG. 3). Since the buffer area does not have electrical circuits formed therein, the area is utilized for forming second via holes 310 in the area, and a conductive material is filled inside the via holes or hole walls to form electrical channels between the upper and lower surfaces of the substrate 318. The second via holes 310 can be formed by employing machine drilling, laser drilling, dry etching, wet etching or other suitable methods, and the conductive metal filled inside can be Sn, Ag, Au, Al, Be, Cu, Ni, Rh, W or the combinations thereof.

A first contact pad 309 and a second contact pad 306 which are the signal transmission paths between inner circuits of the device with the external communication are disposed on the first electronic element layer 313. A first inner conductive layer 307 on the first electronic element 313 is formed by employing sputtering, electroplating or other suitable methods, and circuit signals of the first contact pad 309 and the second contact pad 306 are redistributed. A first cover layer 304 and a second cover layer 305 can be combined into a single cover layer to enhance leveling of the packaging unit surface, and a patterning process can be carried out in between to form a second inner conductive layer 317 and first via holes 308 to reinforce the above circuit signal redistribution, and enables more functionality of the first packaging unit 300 during stacking.

An electronic element grounding layer 311 is formed on the lower surface of the first packaging unit 300, and the grounding layer material can be Cu, Ni, Fe, Al, Co, Au or the combinations thereof. Besides being the electronic element grounding layer, this metal layer is also a good heat conductor which assists in releasing heat energy generated by the first electronic element layer 313. The electronic element grounding layer 311 can form signal channels by employing machining, dry etching, wet etching or laser drilling, and the grounding layer in FIG. 3A is a side view after a patterning process. A first circuit protective layer 303 and a second circuit protective layer 312 are formed on the top and bottom surfaces of the first packaging unit 300 to provide protection for the first inner conductive layer 307, the second inner conductive layer 317 and the electronic element grounding layer 311. The positions of a first signal contact 302, a second signal contact 314, a third signal contact 315, and a fourth signal contact 316 are defined on the protective layers, and the signal contacts can form protective layers (not indicated specifically in FIG. 3) thereon by employing screen printing, stencil printing, cylinder coating, inkjet coating, lithography or any suitable process. Fixation structures 301 are formed on the above signal contact protective layer to connect circuit signals between the first packaging unit 300 and other electronic devices.

As shown in FIG. 3A, the transmission paths of the circuit signals inside the first electronic element layer 313 can be: 1) the second contact pad 306→the first inner conductive layer 307→the second via holes→the electronic element grounding layer 311→the third signal contact 315 (the lower surface of the first packaging unit 300); 2) the first contact pad 309→the second inner conductive layer 317→the first signal contact 302→signal transmission fixation structures 301 (the upper surface of the first packaging unit 300). The electrical signals in the first electronic element layer 313 can be transmitted to the upper and lower surfaces of the first packaging unit 300, as described above, to facilitate stacked packaging. The above structure of the preferred embodiment is for illustration purposes only, and not for limiting the invention.

Corresponding to FIG. 3A, FIG. 3B is a possible bottom view of a first embodiment of the present invention, and for easy illustration, the second circuit protective layer 312 in FIG. 3A is omitted in this diagram. After a patterning process, a first signal channel 321, a second signal channel 325, a third signal channel 326 and a fourth signal channel 327 are formed in the electronic element grounding layer 311. Because the first electronic element layer 313 on the upper surface of the first packaging unit 300 cannot be shown in FIG. 3B, the first electronic element layer 313 is indicated with a dotted line. Grounding signals in the first electronic element layer 313 can be transmitted to the electronic element grounding layer 311 through third via holes 322 to complete the ground of the electronic element. The second via holes are distributed around the first packaging unit 300, and can employ the connection between the third signal channel 326 and the second signal contact 314 to achieve the configuration of the signal contacts. After a patterning process, the electronic element grounding layer 311 can form test dedicated contacts as fifth signal contacts 323, and is coupled to test signals of the electronic element inside the packaging structure to form an electronic packaging structure with a test function. Moreover, wireless signals receiver antenna 324 can be formed through the patterning process, and the first packaging unit 300 can perform wireless signal transmission with the outside world by employing the circular signal channels, It shall be appreciated that the specific embodiment of the invention has been described herein for purposes of illustration rather than limiting the invention.

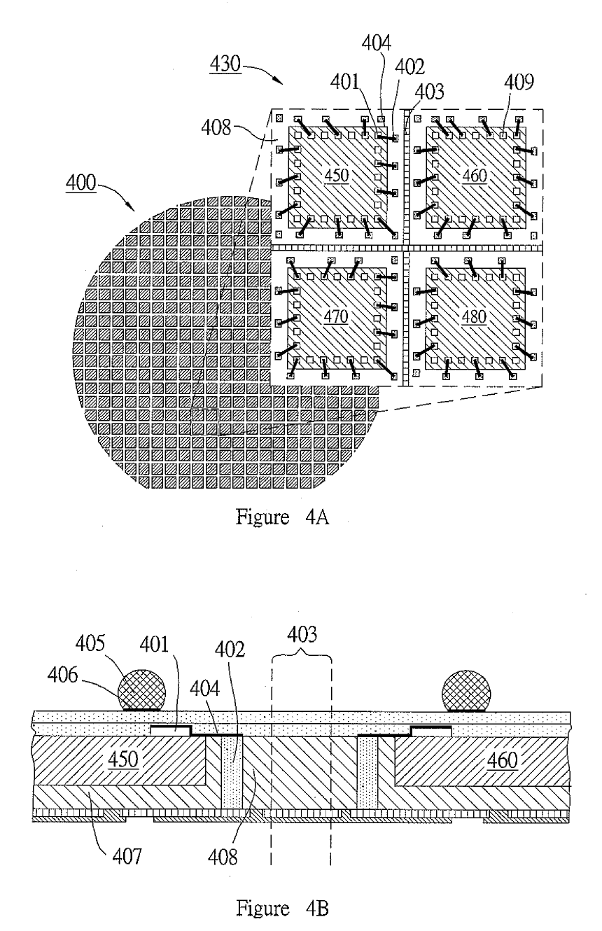

FIG. 4A is an enlarged diagram of a possible distribution on the substrate according to the first embodiment of the present invention. Multiple 3D packaging units with enhanced grounding performance are disposed on a wafer 400, and a first electronic element layer 450, a second electronic element layer 460, a third electronic element layer 470 and a fourth electronic element layer 480 are included in an enlarged area 430 in this top view. A single or multiple second via holes 402 can be formed on a buffer area 408 between the electronic element layers by employing machine drilling, laser drilling, dry etching, or wet etching. The signals inside the first electronic element layer 450 can be transmitted to the electronic element grounding layer on the lower surface of the packaging unit from a first contact pad 401 along a first inner conductive layer 404 to second via holes 402, and the signal contacts on the lower surface of the packaging unit are configured by patterning the grounding layer. Electrical signals inside the second electronic element layer 460 can perform the configuration of the signal contacts on the surface of the packaging unit through second contact pads 409 by employing the method of the first embodiment in FIG. 3A. All the above packaging units are batch manufactured on wafers or substrates, and thus the manufacturing cost of each individual packaging unit can be reduced. The wafer 400 is separated along a wafer scribe line 403 created on the wafer, thereby forming the individual 3D packaging unit with enhanced grounding performance.

Corresponding to the enlarged area in FIG. 4A, FIG. 4B is a possible cross-sectional diagram on the substrate according to the first embodiment of the present invention. The first electronic element layer 450 and the second electronic element layer 460 are on an electronic element substrate 407, and the buffer areas are around the electronic element layers. A first signal contact 406 and a signal transmission fixation structure 405 are on the top of the first electronic element layer 450. The die separating method will be performed on the buffer areas excluding the second via holes 402 along the wafer scribe line 403 shown in the diagram. It shall be appreciated that the specific embodiment of the invention has been described herein for purposes of illustration rather than limiting the invention.

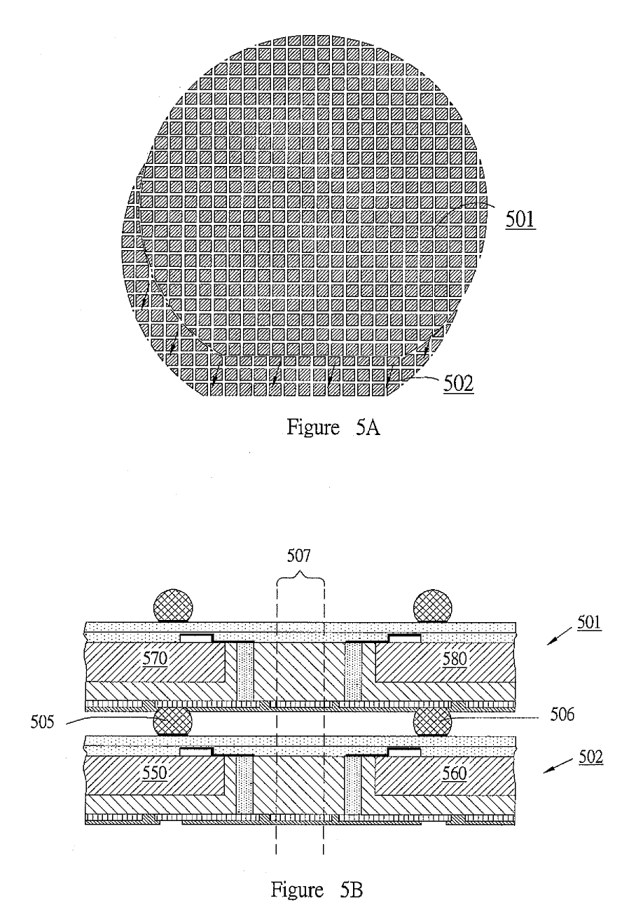

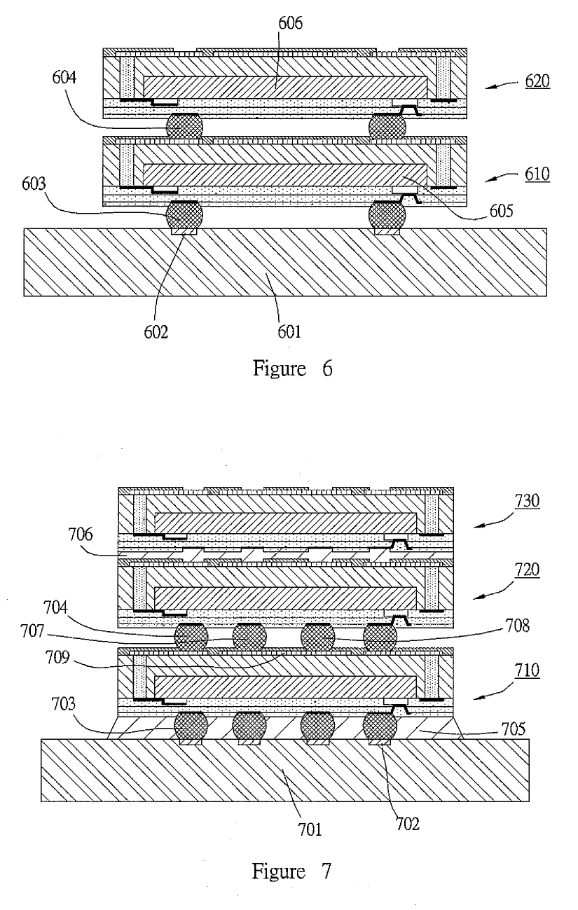

FIG. 5A is a schematic diagram of wafer stacking. Multiple 3D packaging units with enhanced grounding performance of the invention are disposed on a first wafer 501 and a second wafer 502, respectively. The die separation can be performed after the procedure of wafer stacking is completed. As shown in FIG. 5B, the diagram which corresponds to FIG. 5A is a side view of a separating or dicing process after the wafer stacking. In the illustration, a first electronic element layer 550 and a second electronic element layer 560 are on the wafer 502; a third electronic element layer 570 and a fourth electronic element layer 580 are on the first wafer 501. The electronic signals between the first electronic element layer 550 and the third electronic element layer 570 can be transmitted through a first fixation structure 505 having the capability to transmit the signal, and the electronic signals between the second electronic element layer 560 and the fourth electronic element layer 580 can be transmitted through a second fixation structure 506 having the capability to transmit the signal. The wafers are separated or divided along a wafer scribe line 507 on the wafers, thereby forming the individual 3D packaging unit with enhanced grounding performance, as shown in FIG. 6.

FIG. 6 is a second embodiment of the present invention, and a cross-sectional schematic diagram of a first-type stacked packaging configured by the packaging units of the present invention. A first electronic element layer 605 is in a first packaging unit 610, and a second electronic element layer 606 is in a second packaging unit 620. The electronic signals between the two electronic element layers can be transmitted through a second signal transmission fixation structure 604. Signal contacts 602 are formed on a substrate 601. The first packaging unit 610, the second packaging unit 620 and the substrate 601 can form the signal connection by employing a first signal transmission fixation structure 603 to achieve the stacked packaging. It shall be appreciated that the specific embodiment of the invention has been described herein for purposes of illustration rather than limiting the invention.

FIG. 7 is a third embodiment of the present invention, and a cross-sectional schematic diagram of a second-type stacked packaging configured by the packaging units of the present invention. Signal contacts are formed on the corresponding contact nodes of the top and bottom sides of a first packaging unit 710, a second packaging unit 720 and a third packaging unit 730. The electronic signals between the first packaging unit 710 and the second packaging unit 720 can be transmitted through a second signal transmission fixation structure, and the electronic signals between the second packaging unit 720 and the third packaging unit 730 can be transmitted through a signal transmission adhesive material 706. Since the lower surface on the packaging structure of the 3D packaging units with enhanced grounding performance of the invention has a patterned metal layer (the grounding layer), the signal channels can be formed thereon. A first signal channel 709 is formed on the first packaging unit 710 by employing the grounding layer to provide the signal coupling between a third signal transmission fixation structure 707 and a fourth signal transmission fixation structure 708. Signal contacts 702 are on a substrate 701, and the first packaging unit 710, the second packaging unit 720, the third packaging unit and the substrate 701 may construct the signal connection by employing a first signal transmission fixation structure 703 and a second signal transmission fixation structure 704 to achieve the stacked packaging. In order to enhance reliability of the whole packaging structure, an adhesive material 705 can be applied to the surrounding of the fixation structure 703 to enhance the strength thereof. It shall be appreciated that the specific embodiment of the invention has been described herein for purposes of illustration rather than limiting the invention.

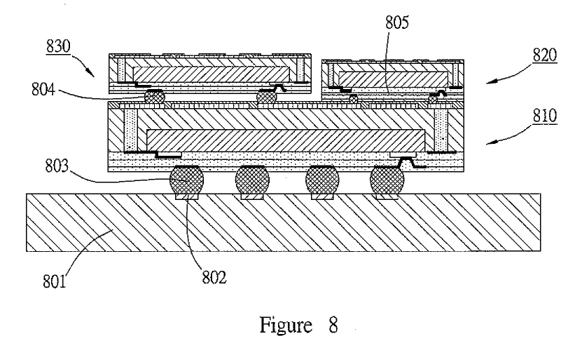

FIG. 8 is a fourth embodiment of the present invention, and a cross-sectional schematic diagram of a third-type stacked packaging configured by the packaging units of the invention. A second packaging unit 820 and a third packaging unit 830 of different sizes are located on a first packaging unit 810. The signal transmission between the first packaging unit 810 and the second packaging unit 820 is carried out by employing a signal transmission adhesive material 805, and the signal transmission between the first packaging unit 810 and the third packaging unit is carried out by employing second signal transmission fixation structures 804. Signal contacts 802 are formed on a substrate 801, and the first packaging unit 810, the second packaging unit 820, the third packaging unit 830 and the substrate 801 can construct the signal connection by employing a first signal transmission fixation structure 803 to achieve the stacked packaging.

From the foregoing, it shall be appreciated that specific embodiments of the invention have been described herein for purposes of illustration, but that various modifications and alterations may be made by those skilled in the art without deviating from the spirit and scope of the invention. Accordingly, the invention is not limited except as by the appended claims.

Having described the invention, the following is claimed:

1. An electronic packaging structure comprising:
a substrate for forming an electronic element;
an electronic element formed on a first surface of said substrate, and the area occupied by said electronic element is smaller than or equal to that of said substrate;
a contact pad disposed on the surface of said electronic element;
a buffer area distributed around said electronic element;
a grounding layer formed on a second surface of said substrate, wherein said buffer area includes a via hole formed thereon, a conductive material being filled inside said via hole or hole wall to construct signal connection between the upper surface of said buffer area and said grounding layer;
signal channels formed on at least one side of said electronic packaging structure; and
signal contacts formed at the ends of said signal channels, and distributed over at least one side of said electronic packaging structure.

2. The electronic packaging structure of claim 1, wherein said signal channels formed on the both sides of said electronic packaging structure establish signal connection through said via hole for signal transmission.

3. The electronic packaging structure of claim 1, wherein the material of said substrate includes Si, Ge, Sn, C, or the combination thereof.

4. The electronic packaging structure of claim 1, wherein the material of said buffer area is the same as said substrate, and said electronic element does not occupy said buffer area.

5. The electronic packaging structure of claim 1, wherein said electronic element includes an active electronic device, a passive electronic device, a sensing device, a testing device, a micro-electro-mechanical chip or the combinations thereof.

6. The electronic packaging structure of claim 1, wherein said grounding layer includes Cu, Ni, Fe, Al, Co, Fe or the combinations thereof.

7. The electronic packaging structure of claim 1, wherein said grounding layer is a heat conductor.

8. The electronic packaging structure of claim 1, wherein said via hole is formed by machine drilling, laser drilling, dry etching, or wet etching.

9. The electronic packaging structure of claim 1, wherein the conductive metal filled inside said via hole includes Sn, Ag, Au, Al, Be, Cu, Ni, Rh, W or the combination thereof.

10. The electronic packaging structure of claim 1, further comprising a protective layer formed on said signal contact by screen printing, stencil printing, coating or lithography.

11. The electronic packaging structure of claim 1, wherein said signal contact can be coupled to the test signals of said electronic element within said electronic packaging structure, thereby forming an electronic packaging structure having a test function.

12. A 3D electronic packaging structure having multiple packaging units comprising:
multiple substrates for forming electronic elements;
multiple electronic elements formed on first surfaces of said multiple substrates, and the areas occupied by said multiple electronic elements are smaller than or equal to those of said multiple substrates;
multiple contact pads disposed on the surfaces of said multiple electronic elements;
multiple buffer areas distributed around said multiple electronic elements;
multiple grounding layers formed on second surfaces of said multiple substrates, wherein said multiple buffer areas include multiple via holes formed thereon, conductive materials being filled inside said multiple via holes or hole walls to construct signal connection between the upper surfaces of said multiple buffer areas and said multiple grounding layers;
multiple signal channels formed on at least one side of said electronic packaging structure;
multiple signal contacts formed at the ends of said multiple signal channels and distributed over at least one side of said electronic packaging structure; and
multiple fixation structures formed on said multiple signal contacts.

13. The 3D electronic packaging structure having multiple packaging units of claim 12, wherein said multiple signal channels on the both sides of said electronic packaging structure establish signal connection through said multiple via holes for signal transmission.

14. The 3D electronic packaging structure having multiple packaging units of claim 12, wherein said multiple signal channels, said multiple fixation structures and said multiple via holes are not only signal transmission mediums inside each individual packaging unit but also signal transmission paths for said multiple electronic elements in the multiple packaging units while performing the packaging units stacking.

15. The 3D electronic packaging structure having multiple packaging units of claim 12, wherein the materials of said multiple substrates include Si, Ge, Sn, C, or the combinations thereof.

16. The 3D electronic packaging structure having multiple packaging units of claim 12, wherein the materials of said buffer areas are the same as said multiple substrates, and said multiple electronic elements do not occupy said multiple buffer areas.

17. The 3D electronic packaging structure having multiple packaging units of claim 12, wherein said multiple electronic elements include active electronic devices, passive electronic devices, sensing devices, testing devices, micro-electro-mechanical chips or the combinations thereof.

18. The 3D electronic packaging structure having multiple packaging units of claim 12, wherein said multiple grounding layers include Cu, Ni, Fe, Al, Co, Au or the combinations thereof.

19. The 3D electronic packaging structure having multiple packaging units of claim 12, wherein said multiple grounding layers are heat conductors.

20. The 3D electronic packaging structure having multiple packaging units of claim 12, wherein said multiple via holes are formed by employing machine drilling, laser drilling, dry etching or wet etching.

21. The 3D electronic packaging structure having multiple packaging units of claim 12, wherein the conductive metals filled inside said multiple via holes include Sn, Ag, Au, Al, Be, Cu, Ni, Rh, W, or the combinations thereof.

22. The 3D electronic packaging structure having multiple packaging units of claim 12, further comprising protective layers formed on said multiple signal contacts by screen printing, stencil printing, coating or lithography.

23. The 3D electronic packaging structure having multiple packaging units of claim 12, wherein said multiple signal contacts can be coupled to the test signals of said multiple electronic elements within said electronic packaging structure, thereby forming an electronic packaging structure having a test function.
